(19) United States
(12) Patent Application Publication
(10) Pub. No.: US 2017/0366176 A1
(43) Pub. Date: Dec. 21, 2017

(54) DETECTION DEVICE

(71) Applicant: WISTRON CORP., New Taipei City (TW)

(72) Inventors: Jiangtao ZHU, New Taipei City (TW); Yongqiang LI, New Taipei City (TW); Lei YANG, New Taipei City (TW); Shaobo PENG, New Taipei City (TW); Jinchao LI, New Taipei City (TW); Meijiao LIANG, New Taipei City (TW)

(73) Assignee: WISTRON CORP., New Taipei City (TW)

(21) Appl. No.: 15/251,150

(22) Filed: Aug. 30, 2016

(30) Foreign Application Priority Data
Jun. 21, 2016 (CN) 201610460425.X

(51) Int. Cl. H03K 5/19; H03B 5/20; G01R 31/14; H05F 3/02; G01R 29/12

(52) U.S. Cl. CPC H03K 5/19; H05F 3/02; G01R 29/12; G01R 31/14; H03B 5/20

(57) ABSTRACT

A detection device has a detecting port, a leakage port, an oscillation circuit and a detection circuit. The detecting port is used for pluggably coupled to an object. The leakage port is electrically coupled to a ground loop. The oscillation circuit is respectively coupled to the detecting port and the leakage port, and used for generating an oscillation signal. When the detecting port is coupled to the object, electrons on the object are transferred to the leakage port via the oscillation circuit. The detection circuit is used for determining whether the detecting port is coupled to the object based on the oscillation characteristic of the oscillation signal.

### CROSS-REFERENCE TO RELATED APPLICATIONS

This non-provisional application claims priority under 35 U.S.C. §119(a) on Patent Application No(s). 201610460425.X filed in China on Jun. 21, 2016, the entire contents of which are hereby incorporated by reference.

### BACKGROUND

### Technical Field

The disclosure relates to a detection device, more particularly to a detection device integrated with an electrostatic protection device.

### Related Art

Nowadays, integrated circuits are very sensitive to electrostatic discharge (ESD). In fabrication plants, when operators and technicians assemble devices, ESD might occur and cause damages on the integrated circuits of the devices. Thus, the operators and technicians of fabrication plants need to wear devices with ESD protection function to prevent the charges on human bodies being conducted to the device to be fabricated.

However, technicians may incorrectly wear ESD protection devices due to various reasons. For example, a technician wears ESD protection device indeed, but the loose port of device causes imperfect contact, the technician wears the protection device by a wrong method, or the technician is too busy to wear the protection device. Therefore, how to find out the above problems immediately and notify the person involved and the related department is an issue to be solved in modern fabrication plants.

### SUMMARY

According to an embodiment, the disclosure provides a detection device, having a detecting port, a leakage port, an oscillation circuit and a detection circuit. The detecting port is used for pluggably coupled to the object to be measured. The leakage port is used for electrically coupled to the ground loop. The oscillation circuit is electrically coupled to the detecting port and the leakage port respectively, and is used for generating an oscillation signal. Also, when the detecting port is coupled to the object, the charges of the object will be transferred to the leakage port via the oscillation circuit. The detection circuit is used for determining whether the detecting port is coupled to the object based on the oscillation characteristic of the oscillation signal.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a circuit diagram of a detection device in an embodiment;

FIG. 2 is a schematic diagram of a detection device in actual use in an embodiment;

FIG. 3A is a timing diagram of an oscillation signal in an embodiment;

FIG. 3B is a timing diagram of an oscillation signal in another embodiment; and

FIG. 4 is a functional block diagram of a detection device in an embodiment.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

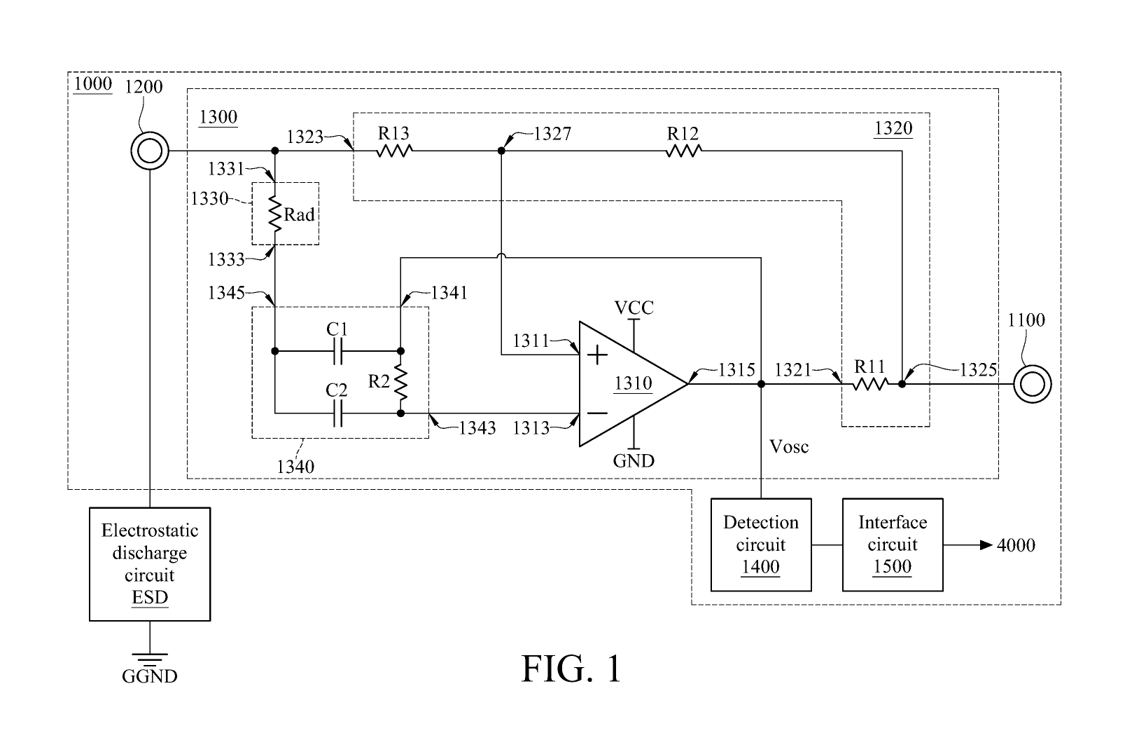

Please refer to FIG. 1, a circuit diagram of a detection device in an embodiment. As shown in FIG. 1, a detection device 1000 has a detecting port 1100, a leakage port 1200, an oscillation circuit 1300 and a detection circuit 1400. Among them, the leakage port 1200 is electrically coupled to a ground loop ESD to contact to the ground terminal of whole environment GGND. The oscillation circuit 1300 is electrically coupled to the detecting port 1100 and the leakage port 1200 respectively. The detection circuit 1400 is electrically coupled to the oscillation circuit 1300.

The oscillation circuit 1300 is used for generating the oscillation signal Vosc. More specifically, the oscillation circuit 1300 has an amplifier 1310, a divided feedback and bleeder circuit 1320, a resistor device 1330 and a harmonic oscillation unit 1340. The amplifier 1310 has a first input 1311, a second input 1313 and an output 1315. The divided feedback and bleeder circuit 1320 has a first terminal 1321, a second terminal 1323, a first node 1325 and a second node 1327. The first terminal 1321 of the divided feedback and bleeder circuit 1320 is coupled to the output 1315 of the amplifier 1310. The second terminal 1323 of the divided feedback and bleeder circuit 1320 is coupled to the leakage port 1200. The first node 1325 of the divided feedback and bleeder circuit 1320 is coupled to the detecting port 1100. The second node 1327 of the divided feedback and bleeder circuit 1320 is coupled to the first input 1311 of the amplifier 1310. The resistor device 1330 has a first terminal 1331 and a second terminal 1333. The first terminal 1331 of the resistor device 1330 is coupled to the leakage port 1200. The harmonic oscillation unit 1340 has a first terminal 1341, a second terminal 1343 and a third terminal 1345. The first terminal 1341 of the harmonic oscillation unit 1340 is coupled to the output 1315 of the amplifier 1310. The second terminal 1343 of the harmonic oscillation unit 1340 is coupled to the input 1313 of the amplifier 1310. The third terminal 1345 of the harmonic oscillation unit 1340 is coupled to the second terminal 1333 of the resistor device 1330. In an embodiment, the oscillation signal Vosc, generated by the oscillation circuit 1300, is not larger than 5 volt with respect to the voltage of the ground terminal GGND.

In an embodiment, the divided feedback and bleeder circuit 1320 is made up of a resistor R11, a resistor R12 and a resistor R13, wherein the resistance of the resistor R11 is 470 kilo ohm (kΩ), the resistance of the resistor R12 is 910 kΩ, and the resistance of the resistor R13 is 100 kΩ. Besides, the resistance of resistor device 1330 is no less than 10 kΩ.

In an embodiment, as shown in FIG. 1, the harmonic oscillation unit 1340 has a resistor R2, a first capacitor C1 and a second capacitor C2. The resistor R2 is coupled to the first terminal 1341 of the harmonic oscillation unit 1340 and the second terminal 1343 of the harmonic oscillation unit 1340 respectively. The first capacitor C1 is coupled to the first terminal 1341 of the harmonic oscillation unit 1340 and the third terminal 1345 of the harmonic oscillation unit 1340 respectively. The second capacitor C2 is coupled to the third terminal 1345 of the harmonic oscillation unit 1340 and the second terminal 1343 of the harmonic oscillation unit 1340 respectively. In this embodiment, the resistance of the resistor R2 is 470 kΩ, the capacitances of the first capacitor C1 and the second capacitor C2 are both 470 pico Farad pF. However, the above description is just for example. Person having ordinary skill in the art can determine the value of every electronic component based on the spirit of this disclosure and this disclosure does not intend to limit the value of these electronic components.

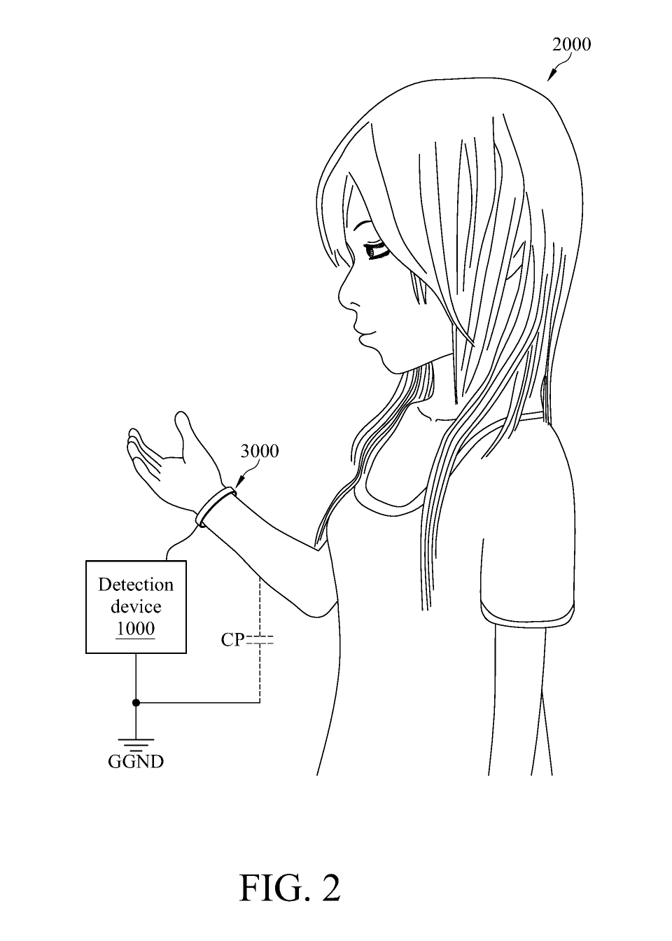

Please refer to FIG. 1 and FIG. 2, wherein FIG. 2 is a schematic diagram of a detection device in actual use in an embodiment. As shown in FIG. 2, a personnel 2000 wears an electrostatic protection wristband 3000, the electrostatic protection wristband 3000 is plugged in the detecting port of the detection device 1000 (not clearly shown in the figure). The electrostatic charges on the personnel 2000 are transferred via the detecting port 1100, the divided feedback and bleeder circuit 1320 of the oscillation circuit 1300 in the detection device 1000 to the leakage port 1200. Afterwards, the charges flow from the leakage port 1200, via the ground loop ESD, to the ground terminal GGND.

More specifically, the inner margin of the electrostatic protection wristband 3000 has an exposed conducting loop. When the electrostatic protection wristband 3000 is plugged in the detecting port 1100, the conducting loop is electrically coupled to the detecting port. Thus, when the personnel 2000 wears the electrostatic protection wristband 3000 correctly, the charges on the hand of the personnel 2000 are transferred to the detecting port 1100 via the exposed conducting loop, and are finally transmitted to the ground terminal GGND. If the electrostatic protection wristband 3000 is plugged in the detecting port 1100 incorrectly or the eversion of the inner margin of the electrostatic protection wristband 3000 makes the conducting loop disconnect with the hand of the personnel 2000, the charges on the hand of the personnel 2000 are not transmitted to the ground terminal GGND.

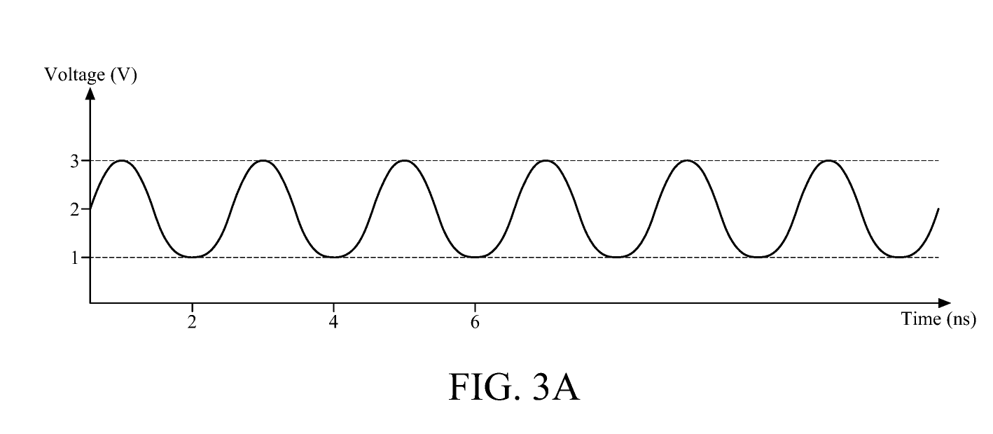

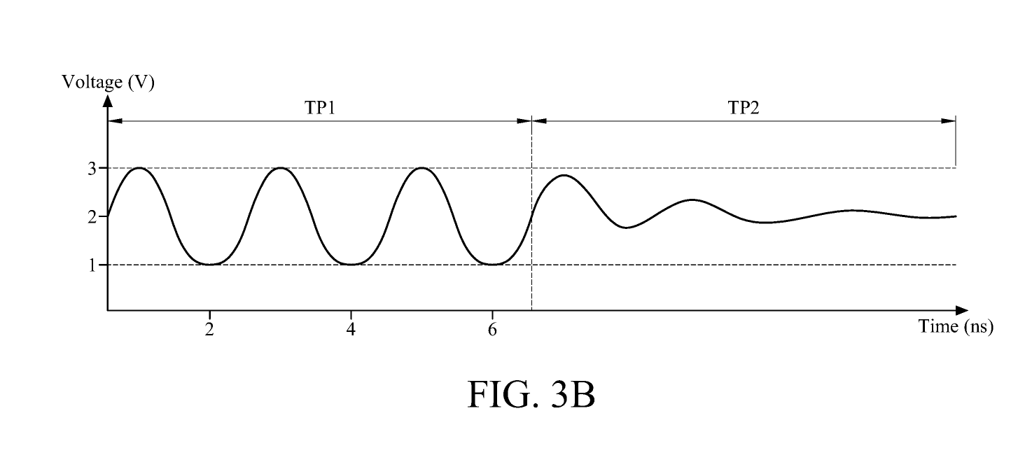

Please refer to FIG. 3A and FIG. 3B, wherein FIG. 3A is a timing diagram of an oscillation signal in an embodiment, and FIG. 3B is a timing diagram of an oscillation circuit in another embodiment. In an embodiment, when the personnel 2000 is not really electrically coupled to the detection device 1000, the oscillation signal generated by the oscillation circuit 1300 is shown in FIG. 3A. In another embodiment, when the personnel 2000 is correctly electrically coupled to the detection device 1000, the oscillation signal generated by the oscillation circuit 1300 is shown in FIG. 3B. More specifically, please back to FIG. 2. Because there is a parasitic capacitor CP for the personnel 2000 with respect to the ground terminal, when the personnel 2000 is correctly electrically coupled to the detection device 1000, the existence of the parasitic capacitor CP breaks the oscillation conditions of the oscillation circuit based on Barkhausen stability criterion. The result is shown in FIG. 3B, wherein in time interval TP1, the personnel 2000 doesn't wear the electrostatic protection wrist band 3000, and in time interval TP2, the personnel 2000 correctly wears the electrostatic protection wristband 3000. Thus, in time interval TP2, the amplitude of the oscillation signal must become smaller and smaller, and finally stop oscillating.

The detection circuit 1400 is electrically coupled to the output 1315 of the amplifier 1310 of the oscillation circuit 1300. Therefore, the detection circuit 1400 can detect the oscillation characteristic of the oscillation signal Vosc to determine whether the personnel 2000 is correctly electrically coupled to the detecting port 1100 of the detection device 1000. More specifically, when the detection circuit 1400 detects no periodic voltage change of the oscillation signal Vosc, based on the theory mentioned before, the detection circuit 1400 determines that the personnel 2000 is correctly electrically coupled to the detecting port 1100. In other words, the personnel 2000 uses a right method to wear the electrostatic protection wristband 3000, and the electrostatic protection wristband 3000 is well plugged in the detecting port 1100 of the detection device 1000. Moreover, according to embodiments in FIG. 3A, FIG. 3B and FIG. 1, followed by the voltage restriction of the oscillation signal Vosc, because the value of the current flowing from the oscillation circuit 1300 to human body is very tiny, the current won't affect the electrostatic protection of the personnel 2000 by the detection device 1000. Besides, when the electrostatic protection wristband 3000 is correctly coupled to the detection device 1000, the oscillation signal Vosc will decay fast and converge to smaller than 5 volt. The ESD protection of the detection device 1000 for the personnel 2000 is not affected in the aforementioned situation.

If the detection circuit 1400 detects the periodic voltage change of the oscillation signal Vosc, the detection circuit 1400 will determine that the personnel 2000 is incorrectly electrically coupled to the detecting port 1100. In other words, the result is from either the incorrect wearing of the electrostatic protection wristband 3000 of the personnel 2000, or imperfect contact between the electrostatic protection wristband 3000 and the detecting port 1100 of the detection device 1000.

In an embodiment, due to the differences in body size and gender of each person, the value of the capacitor on a person with respect to the ground terminal GGND of environment varies from person to person. In order to accurately detect whether the personnel 2000 correctly wears the electrostatic protection wristband 3000 or not, the oscillation circuit 1300 needs calibrating appropriately. As shown in FIG. 1, the resistor device 1330 includes a variable resistor Rad. When the detection device 1000 is used by the personnel 2000 in the first time, the personnel 2000 has operated the detection device 1000 to adjust the value of the variable resistor Rad until the detection circuit 1400 of the detection device 1000 produces a correct determining result of the personnel 2000 and the detection device 1000. Hence, the calibration is completed.

In an embodiment, please back to FIG. 1. The detection device 1000 is further electrically coupled to a bus network 4000, for example, an inter-integrated circuit, RS-485 or other similar master-slave architecture bus. Besides, the detection circuit 1400 sends the determining result to the bus network 4000.

More specifically, the detection device 1000 further has an interface circuit 1500. The interface circuit 1500 is respectively electrically coupled to the detection circuit 1400 and the bus network 4000. Thus, when the detection circuit 1400 runs normally, the interface circuit 1500 receives the determining result from the detection circuit 1400 and sends to the bus network 4000. When the detection circuit 1400 is failed, in an embodiment, the detection circuit 1400 sends the same determining result repeatedly. If the interface circuit 1500 gets the constant determining result from the detection circuit 1400 continuously, the interface circuit 1500 will not send this repeat determining result to the bus network 4000. In the protocol architecture of the bus network 4000, if one of the multiple detection devices connected by the bus network 4000 malfunctions, the problems, including the defect detection device occupying the bus network 4000 continuously and the signal confliction of the bus network 4000, can be avoided because of the function of the interface circuit 1500.

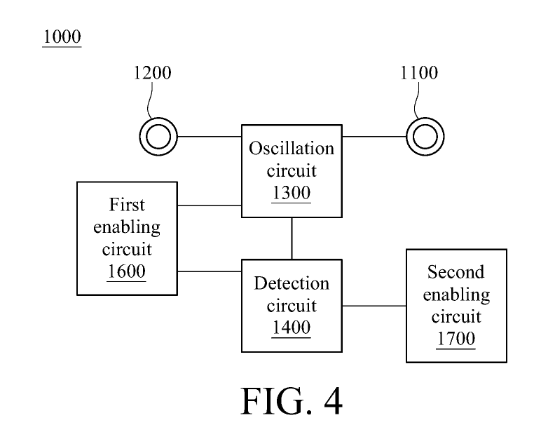

In an embodiment, as shown in FIG. 4, the detection device 1000 further has a first enabling circuit 1600 electrically connected to the oscillation circuit 1300 and the detection circuit 1400. The first enabling circuit 1600 is used for selectively disabling the oscillation circuit 1300. More specifically, the first enabling circuit 1600 is used for selectively decreasing the electric potential of the power terminal VCC of the amplifier 1310 in order to make the amplifier 1310 functioning abnormally. Thus, the oscillation signal Vosc generated by the oscillation circuit 1300 is blocked from oscillating, and the detection circuit 1400 is blocked from sending the abnormal determining result. In practice, when the personnel 2000 temporarily leave the seat and does not need to wear the electrostatic protection wristband 3000, the personnel 2000 operates the detection device 1000 to make the first enabling circuit 1600 disable the oscillation circuit 1300. At this moment, the first enabling circuit 1600 also sends out the signal to inform the detection circuit 1400. Therefore, the detection circuit 1400 sends the information that the detection device 1000 stops detecting to the bus network 4000. When the personnel 2000 is back to the seat and operates the detection device 1000, the first enabling circuit 1600 will enable the oscillation circuit 1300 again. Then, the detection circuit 1400 also restarts detecting, and sends the information detected to the bus network 4000.

In another embodiment, as shown in FIG. 4, the detection device 1000 further has a second enabling circuit 1700 electrically connected to the detection circuit 1400. And, the second enabling circuit 1700 is used for selectively adjust the determining result. In brief, in this embodiment, when the personnel 2000 temporarily leave the seat and does not need to wear the electrostatic protection wristband 3000, the personnel 2000 operates the detection device 1000 to make the second enabling circuit 1700 notify the detection circuit 1400. So, the detection circuit 1400 will not detect the oscillation signal Vosc practically, and the detection circuit 1400 will send the information that the detection device 1000 stops detecting to the bus network 4000. When the personnel 2000 is back to the seat and operate the detection device 1000, the second enabling circuit 1700 will notify the detection circuit 1400 to restart detecting, and send the information detected to the bus network 4000.

As set forth above, the detection device provided in this disclosure can detect whether the detecting port is coupled to the object (personnel), and at the same time, transmit the charges on the object to the leakage port via the oscillation circuit. As a result, the detection device provided in this disclosure practically has the function of electrostatic discharge protection.

What is claimed is:

1. A detection device, comprising:
a detecting port used for pluggably coupled to an object;
a leakage port used for electrically coupled to a ground loop;
an oscillation circuit electrically coupled to the detecting port and the leakage port respectively, used for generating an oscillation signal, and when the detecting port coupled to the object, charges of the object are transferred to the leakage port via the oscillation circuit; and
a detection circuit determining whether the detecting port is coupled to the object based on an oscillation characteristic of the oscillation signal to generate a judgment result.

2. The detection device according to claim 1, wherein the oscillation circuit comprises:
an amplifier having a first input, a second input and an output;
a divided feedback and bleeder circuit having a first terminal, a second terminal, a first node and a second node, wherein the first terminal of the divided feedback and bleeder circuit is coupled to the output of the amplifier, the second terminal of the divided feedback and bleeder circuit is coupled to the leakage port, the first node of the divided feedback and bleeder circuit is coupled to the detecting port, the second node of the divided feedback and bleeder circuit is coupled to the first input of the amplifier;
a resistor device having a first terminal and a second terminal, wherein the first terminal of the resistor is coupled to the leakage port; and
a harmonic oscillation unit having a first terminal, a second terminal and a third terminal, wherein the first terminal of the harmonic oscillation unit is coupled to the output of the amplifier, the second terminal of the harmonic oscillation unit is coupled to the second input of the amplifier, the third terminal of the harmonic oscillation unit is coupled to the second terminal of the resistor.

3. The detection device according to claim 2, wherein the resistor comprises a variable resistor.

4. The detection device according to claim 2, wherein the harmonic oscillation unit comprises:
a resistor coupled to the first terminal of the harmonic oscillation unit and the second terminal of the harmonic oscillation unit respectively;
a first capacitor coupled to the first terminal of the harmonic oscillation unit and the third terminal of the harmonic oscillation unit respectively; and
a second capacitor coupled to the third terminal of the harmonic oscillation unit and the second terminal of the harmonic oscillation unit respectively.

5. The detection device according to claim 2, wherein the detection circuit is coupled to the output of the amplifier.

6. The detection device according to claim 1, wherein a voltage level of the oscillation signal with respect to the ground loop is less than or equal to 5 volt.

7. The detection device according to claim 1, further comprising an enabling circuit electrically coupled to the detection circuit, and used to selectively adjust the judgment result.

8. The detection device according to claim 1, further comprising an enabling circuit electrically coupled to the oscillation circuit, and used to selectively enable the oscillation circuit.

9. The detection device according to claim 1, wherein the detection circuit further sends the judgment result to a bus network.

10. The detection device according to claim 9, further comprising a interface circuit electrically coupled to the detection circuit and the bus network respectively, wherein when the detection circuit is failed, the interface circuit blocks the detection circuit from sending the judgment result to the bus network.
